(19) United States
(12) Patent Application Publication
(10) Pub. No.: US 2006/0029166 A1
(43) Pub. Date: Feb. 9, 2006

(54) SOFT ADAPTIVE VITERBI EQUALIZING METHOD AND RELATED APPARATUS THEREOF

(76) Inventor: Zing-Wei Kang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/161,524

(22) Filed: Aug. 7, 2005

(30) Foreign Application Priority Data
Aug. 9, 2004 (TW) 093123841

(51) Int. Cl. H03D 1/00

(52) U.S. Cl. 375/341; 375/343

(57) ABSTRACT

An adaptive Viterbi equalizing method and a related apparatus are disclosed. The apparatus includes a match filter for equalizing a plurality of original symbols of a received signal to generate a plurality of equalized symbols according to a plurality of channel responses, a Viterbi detector for generating a soft-decision value corresponding to a specific original symbol and generating a plurality of hard-decision values corresponding to the original symbols according to the equalized symbols, and an adaptive channel estimation circuit for generating a reproduced symbol through utilizing the channel responses and the hard-decision values and for adjusting one of the channel responses through utilizing the soft-decision value and a difference between the reproduced symbol and the specific original symbol.

### BACKGROUND OF THE INVENTION

1. Field of the Invention

The invention relates to a receiving apparatus and signal equalizing method, and more particularly, to a receiving apparatus capable of adaptively equalizing a received signal and the related method thereof.

2. Description of the Prior Art

Global System for Mobile Communications (GSM) has gained popularity in recent years. Unfortunately, the Gaussian Minimum Shift Keying (GMSK) modulation applied in the GSM system often suffers from serious Inter-Symbol Interference (ISI). To overcome the ISI most receivers comprise a Viterbi equalizer to the front-end. The Viterbi equalizer processes the channel estimation in an effort to reduce the negative influence of the ISI. Additionally, when the Viterbi equalizer of the receiver estimates the channel response according to a training sequence of a received packet, the receiver also speculates the multi-path fading of the communication channel according to the channel response and attempts to reduce the influence of the multi-path fading accordingly.

Please refer to FIG. 1. FIG. 1 is a functional block diagram of a prior art Viterbi equalizer 10. The Viterbi equalizer 10 comprises a channel estimating unit 12, a match filter 14, and a Viterbi detector 16. Firstly, the channel estimating unit 12 estimates a plurality of channel responses h₀, . . . , hᵢ according to the prior art training sequence, wherein “i” is a positive integer. Secondly, the match filter 14 generates the equalized symbol Zₖ by utilizing the channel responses h₀, . . . , hᵢ and a plurality of original symbol Xₖ of the received signal according to the following equation.
Zₖ=Σₗ₌₀ⁿXₖ₋ₗ·hₗ Equation (1)

Finally, the match filter 14 outputs the equalized symbol Zₖ to the Viterbi detector 16. The Viterbi detector 16 further computes a hard-decision value utilizing the equalized symbol Zₖ and the channel response h₀, . . . , hᵢ according to the Maximum Likelihood Sequence Estimation (MLSE).

Please refer to FIG. 2. FIG. 2 is a schematic diagram of a prior art data burst 50 of a GSM system. As shown in FIG. 2, the data burst 50 comprises a plurality of data blocks D1 and D2, mid-amble M, tails T1 and T2, and guard intervals GI₁ and GI₂. The guard intervals alleviate inter-symbol interference. It is obvious from FIG. 2 that the data between the guard intervals GI₁ and GI₂ separate into two symmetric parts. Each of the data blocks D1 and D2 comprises 58 symbols, wherein the data block D1 comprises symbols D₀′˜D₅₇′ and the data block D2 comprises symbols D₀˜D₅₇. The mid-amble M (i.e., the training sequence mentioned above) comprises 26 symbols for the estimation of channel responses corresponding to the data burst. The symbols M₀˜M₁₂ are located to the right of the doted line 52 and the symbols M₀′˜M₁₂′ are located to the left of the doted line 52. The data burst 50 is processed utilizing the Viterbi equalizer 10 as shown in FIG. 1. Firstly, the mid-amble M (i.e., the symbols M₀′˜M₁₂′ and the symbols M₀˜M₁₂) are utilized to produce a channel estimating process for generating a plurality of fixed channel responses: h₀, . . . , hᵢ. Secondly, the receiver transmits the data block D2 to the Viterbi equalizer 10 in series according to the arrow 56. The symbols D₀˜D₅₇ of the data block D2 are equalized according to the fixed channel response h₀, . . . , hᵢ. Finally, the receiver generates a plurality of hard-decision values by producing a Viterbi detection utilizing the inputted symbols D₀˜D₅₇. In the same way, the receiver transmits the data block D1 to the Viterbi equalizer 10 in series according to the arrow 54, and equalizes the symbols D₀′˜D₅₇′ of the data block D1 according to the channel response h₀, . . . , hᵢ, and generates a plurality of hard-decision values by producing a Viterbi detection with the inputted symbol symbols D₀′˜D₅₇′.

Unfortunately, multi-path fading becomes heavier when the receiver is moving fast. Although the hard-decision values corresponding to the symbols near the mid-amble M can be generated correctly by processing the data block 50 according to the fix channel response h₀, . . . , hᵢ, the hard-decision values corresponding to the symbols far from the mid-amble M may be generated incorrectly even when generated in the same manner. As a result, the signal quality of the receiver decreases.

### SUMMARY OF THE INVENTION

It is therefore one objective of the claimed invention to provide an adaptive Viterbi equalizer and the method thereof for adjusting the channel responses dynamically in response to the variation of multipath fading.

According to the claimed invention, a receiving apparatus is disclosed. The receiving apparatus comprises a match filter, a Viterbi detector, and an adaptive channel estimation circuit. The match filter is utilized to generate a plurality of equalized symbols by equalizing a plurality of original symbols of a received signal according to a plurality of channel responses. The Viterbi detector, coupling to the match filter, is utilized to generate a soft-decision value corresponding to a specific original symbol according to the plurality of equalized symbols, and for generating a plurality of hard-decision values corresponding to the plurality of original symbols. The adaptive channel estimation circuit, electrically connected to the Viterbi detector and the match filter, is utilized to generate a reconstructed symbol according to the plurality of hard-decision values and the plurality of channel responses, and to adjust the plurality of channel responses according to the soft-decision value and an error amount between the reconstructed symbol and the specific original symbol.

According to the claimed invention, an adaptive Viterbi equalizing method is disclosed. The adaptive Viterbi equalizing method comprises (a) generating a plurality of equalized symbols by equalizing a plurality of original symbols of a received signal according to a plurality of channel responses; (b) generating a soft-decision value corresponding to a specific original symbol according to the plurality of equalized symbols and generating a plurality of hard-decision values corresponding to the plurality of original symbols; and (c) generating a reconstructed symbol according to the plurality of hard-decision values and the plurality of channel responses, and adjusting the plurality of channel responses according to the soft-decision value and an error amount between the reconstructed symbol and the specific original symbol.

The adaptive Viterbi equalizer utilizes an adaptive channel estimation circuit to dynamically calibrate the channel responses according to the inputted symbol. As a result, the accuracy of the Viterbi detector improves. Furthermore, the signal quality of the receiver applying the Viterbi detector increases accordingly.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a prior art Viterbi equalizer.

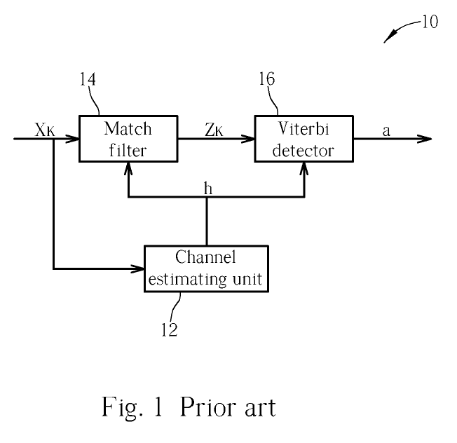

FIG. 2 is a schematic diagram of a prior art GSM data burst.

FIG. 3 is a block diagram of an adaptive Viterbi equalizer according to an embodiment of the present invention.

### DETAILED DESCRIPTION

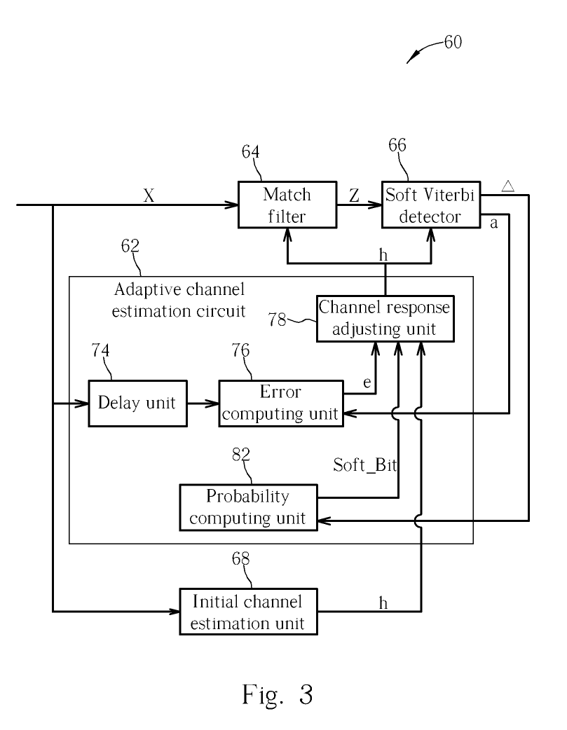

Please refer to FIG. 3. FIG. 3 is a block diagram of an adaptive Viterbi equalizer 60 according to an embodiment of the present invention. The adaptive Viterbi equalizer 60 applied in a Global System for Mobile Communications (GSM) comprises an adaptive channel estimation circuit 62, a match filter 64, a soft Viterbi detector 66, and an initial channel estimation unit 68. The adaptive channel estimation circuit 62 comprises a delay unit 74, an error computing unit 76, a channel response adjusting unit 78, and a probability computing unit 82. Firstly, the initial channel estimation unit 68 generates a plurality of initial values h_{0,0}, h_{0,1}, h_{0,2}, and h_{0,3} from a plurality of channel responses according to a training sequence of the received signal X. Secondly, the match filter 64 equalizes the plurality of original symbols X₀, X₁, . . . , Xᵢ according to the channel response h_{k,0}, h_{k,1}, h_{k,2}, and h_{k,3} to generate a plurality of equalized symbols Z₀, Z₂, . . . , Zᵢ, and the soft Viterbi detector 66 generates a plurality of hard-decision values by producing a prior art Viterbi detection according to the channel response h_{k,0}, h_{k,1}, h_{k,2}, h_{k,3} and the equalized symbols Z₀, Z₂, . . . Zᵢ. Lastly, a soft-decision value A is generated standing for the reliability of the hard-decision values.

Please note, channel responses h_{k,0}, h_{k,1}, h_{k,2}, and h_{k,3} utilized by the match filter 64 and the soft Viterbi detector 66 are not limited to the initial channel response h_{0,0}, h_{0,1}, h_{0,2}, and h_{0,3}. That is to say the channel response h_{k,0}, h_{k,1}, h_{k,2}, and h_{k,3} can be adjusted dynamically according to the present embodiment. The adaptive channel estimation circuit 62 adjusts the channel responses h_{k,0}, h_{k,1}, h_{k,2}, and h_{k,3} according to a hard-decision value a, the soft-decision value A, and the received signal X. That is, the original channel response h_{k,0}, h_{k,1}, h_{k,2}, and h_{k,3} are updated with new channel responses h_{k+1,0}, h_{k+1,1}, h_{k+1,2}, and h_{k+1,3} that are generated according to the received signal X, the hard-decision value a, and the soft-decision value A. The detail description of updating the channel response h_{k,0}, h_{k,1}, h_{k,2}, and h_{k,3} are described in the following paragraphs.

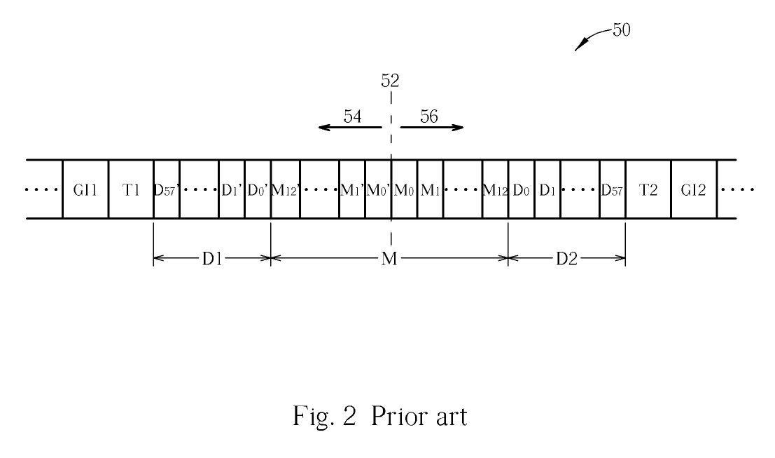

Please refer to FIG. 2 and FIG. 3. The dotted line 52 separates the mid-amble M in the received packet into two parts. According to the present embodiment, a plurality of original symbols to the left of the dotted line 52 are processed in series according to the arrow 54. Next the remaining original symbols are processed in series according to the arrow 56. The adaptive Viterbi equalizer 60 processes the original symbols M₀, M₁, . . . M₁₂, D₀, D₁, . . . D₅₇ one by one. After receiving the data burst it then processes the plurality of original symbols M₀′, M₁′, . . . , M₁₂′ and D₀′, D₁′, . . . , D₅₇′ one by one. Please note that for the sake of brevity only the plurality of original symbol M₀, M₁, . . . , M₁₂ and D₀, D₁, . . . , D₅₇ to the right of the dotted line 52 are utilized to explain the operation of the adaptive Viterbi equalizer 60.

Please refer to FIG. 3. In the present embodiment, the initial channel estimation unit 68 firstly generates four initial channel responses h_{0,0}, h_{0,1}, h_{0,2}, and h_{0,3} according to the training sequence (i.e., the mid-amble M shown in FIG. 2). The symbols M₀, M₁, . . . , M₁₂, for example, are utilized to generate the four initial channel responses h_{0,0}, h_{0,1}, h_{0,2}, and h_{0,3}. Secondly, the initial channel responses h_{0,0}, h_{0,1}, h_{0,2}, and h_{0,3} are transmitted to the match filter 64 and the soft Viterbi detector 66 through the channel response adjusting unit 78. The match filter 64 utilizes the channel responses h_{0,0}, . . . , h_{0,3} by equalizing the plurality of symbols M₀, M₁, . . . , M₁₂ for generating a plurality of equalized symbols Z₀, Z₁, . . . , Z₁₂ corresponding to the symbols M₀, M₁, . . . , M₁₂, respectively. Thirdly, the soft Viterbi detector 66 also utilizes the channel responses h_{0,0}, . . . , h_{0,3} by computing the soft-decision valueΔ₀, Δ₁, . . . , Δ₁₂ and generating a plurality of hard-decision values a₀, a₁, . . . , a₁₂ corresponding to the equalized symbols Z₀, Z₁, . . . , Z₁₂, respectively. Fourthly, the probability computing unit 82 computes a mean value and a variance of the soft-decision values Δ₀, Δ₁, . . . , Δ₁₂, for computing the correct probability Soft_Bitₖ of the hard-decision value aₖ (k>12) according to the following equation:

$${Soft\_Bit}_{k} = 2 \cdot \frac{1}{1 + {ⅇ}^{- \frac{Mean}{Var} \times {Δ}_{k}}} - 1 \qquad Equation ( 2 )$$

The Mean denotes the mean value mentioned above, and Var denotes the variance mentioned above.

In addition, the delay unit 34 delays the original symbol X (i.e., X₀=M₀, X₁=M₁, . . . , X₁₃=D₀ . . . ) inputted according to a predetermined time d relating to the time utilized by the match filter 64 and the soft Viterbi detector 66 for generating the hard-decision value and the soft-decision value from a original symbol. Then, the delayed original symbol X is transmitted to the error computing unit 76 for generating a reproduced symbol rₖ according to the channel responses h_{k-1,0}, . . . , h_{k-1,3}, and the plurality of hard-decision values a_{k-d-0}, a_{k-d-1}, . . . , a_{k-d-3}. If the adaptive Viterbi equalizer 60 operates properly then the reconstructed symbol rₖ is equal to the original symbol Xₖ. The error amount between the reconstructed symbol rₖ and the original symbol Xₖ are utilized to update the channel responses h_{k,0}, . . . , h_{k,3}, so as to generate the following hard-decision value aₖ correctly. The operation of the error computing unit 76 is shown in the following equation:

$$\begin{matrix}{r}_{k} = {\sum }_{l = 0}^{3} {h}_{k - 1 , l} \cdot {a}_{k - d - l} & Equation ( 3 ) \\ {e}_{k - d} = {X}_{k - d} - {r}_{k} & Equation ( 4 )\end{matrix}$$

Finally, the channel response adjusting unit 78 updates the channel responses h_{k-1,0}, . . . , h_{k-1,3} by generating the new channel responses h_{k,0}, . . . , h_{k,3} according to the error amount e_{k-d} and the correct probability Soft_Bitₖ, then transmits the new channel responses h_{k,0}, . . . , h_{k,3} to the match filter 64 and the soft Viterbi detector 66. That is, the match filter 64 and the soft Viterbi detector 66 process the following original symbols according to a more precise channel response h_{k,0}, . . . , h_{k,3}. The operation of the channel response adjusting unit 78 is shown in the following equation:
h_{k,i}=h_{k-1,}i+μ·Soft_Bit_{k-i-d}·eₖ_{d} Equation (5)

As shown in the Equation (5), the parameter μ is determined by the receiver or can be adjustable based on the variation of environment. The parameter μ determines the adjusting range of the channel response h_{k,i}. As the parameter μ becomes larger, the channel response h_{k,I} approaches an optimum value at an increasing rate. Adopting a very large value for the adjusting range is acceptable when the error amount e and the correct probability Soft_Bit is correct. However, when the error amount e and the correct probability Soft_Bitₖ are both wrong the resulting huge adjusting range may cause oscillation of the channel response. In summary, when the adaptive Viterbi equalizer 60 receives an original symbol X, the channel response h_{k,1} is adjusted dynamically according to the error amount e and the correct probability Soft_Bitₖ. As a result, the match filter 64 and the soft Viterbi detector 66 utilize the finely adjusted channel response h_{k,1} to improves the signal quality of the receiver accordingly.

In the same manner, the adaptive Viterbi equalizer 60 individually processes the plurality of original symbols (i.e., original symbols M₀′, M₁′, . . . , M₁₂′, D₀′, D₁′, . . . , D₅₇) to the left of the dotted line 52. As a result, the Equations (2)˜(5) can be easily modified by people skilled in this art through replacing the original symbols M₀, M₁, . . . , M₁₂, D₀, D₁, . . . D₅₇ with the original symbols M₀′, M₁′, . . . , M₁₂′, D₀′, D₁′, . . . , D₅₇′, so as to dynamically adjust the channel response h_{k,1}.

Contrast to the prior art, the adaptive Viterbi equalizer and the related method is capable of calibrating the channel response when processing the input data. As a result, the correct probability of the hard-decision values is ensured even when the multipath fading is serious.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A receiving apparatus comprising:
a match filter for generating a plurality of equalized symbols by equalizing a plurality of original symbols of a received signal according to a plurality of channel responses;
a Viterbi detector, coupling to the match filter, for generating a soft-decision value corresponding to a specific original symbol according to the plurality of equalized symbols, and for generating a plurality of hard-decision values corresponding to the plurality of original symbols according to the plurality of equalized symbols; and
an adaptive channel estimation circuit, coupling to the Viterbi detector and the match filter, for generating a reconstructed symbol according to the plurality of hard-decision values and the plurality of channel responses, in order to adjust the plurality of channel responses according to the soft-decision value and an error amount between the reconstructed symbol and the specific original symbol.

2. The receiving apparatus of claim 1, wherein the received signal comprises a training sequence, the receiving apparatus further comprising:
an initial channel estimation unit, coupling to the adaptive channel estimation circuit, for generating an initial value of the plurality of channel response according to the training sequence.

3. The receiving apparatus of claim 1, wherein the adaptive channel estimation circuit comprises:
a delay unit, for generating a delay signal by delaying the received signal for a predetermined time;
an error computing unit, coupling to the delay unit and the Viterbi detector, for generating the error amount according to the delay signal, the plurality of channel responses, and the plurality of hard-decision values;
a probability computing unit, coupling to the Viterbi detector, for generating a correct probability of detection according to the soft-decision value; and
a channel response adjusting unit, coupling to the match filter, the Viterbi detector, the error computing unit, and the probability computing unit, for adjusting the plurality of channel responses according to the correct probability of detection and the error amount.

4. The receiving apparatus of claim 3, wherein the predetermined time corresponds to a sum of the time for the match filter to equalize the specific original symbol and the time for the Viterbi detector to generate the soft-decision value corresponding to the specific original symbol.

5. The receiving apparatus of claim 3, wherein before the adaptive channel estimation circuit starts to adjust the plurality of channel responses, the match filter equalizes the training sequence according to the initial value of the plurality of channel responses, the Viterbi detector generates a plurality of soft-decision values corresponding to the training sequence according to the training sequence, the probability computing unit generating a mean value and a variance according to the plurality of soft-decision values corresponding to the training sequence; and after the adaptive channel estimation circuit starts to adjusting the plurality of channel responses, the probability computing unit starts to generate the correct probability of detection according to the mean value, variance, and the soft-decision value.

6. The receiving apparatus of claim 3, wherein the channel response adjusting unit adjusts the plurality of channel responses by utilizing a product of the correct probability of detection and the error amount.

7. The receiving apparatus of claim 6, wherein the channel response adjusting unit controls an adjusting range of the plurality of channel responses by regulating the product according to an adjusting coefficient.

8. The receiving apparatus of claim 1, wherein the adaptive channel estimation circuit adjusting the plurality of channel responses according to the soft-decision value and the error amount between the specific original symbol and the reconstructed symbol for updating the plurality of channel responses utilized by the match filter for equalizing the specific original symbol.

9. The receiving apparatus of claim 1, applied in a Global System for Mobile Communications (GSM).

10. An adaptive Viterbi equalizing method of a receiving apparatus comprising:
(a) generating a plurality of equalized symbols by equalizing a plurality of original symbols of a received signal according to a plurality of channel responses;
(b) generating a soft-decision value corresponding to a specific original symbol according to the plurality of equalized symbols, and generating a plurality of hard-decision values corresponding to the plurality of original symbols; and
(c) generating a reconstructed symbol according to the plurality of hard-decision values and the plurality of channel responses to adjust the plurality of channel responses according to the soft-decision value and an error amount between the reconstructed symbol and the specific original symbol.

11. The adaptive Viterbi equalizing method of claim 10, wherein the received signal comprises a training sequence, the adaptive Viterbi equalizing method further comprises:
generating an initial value of the plurality of channel responses according to the training sequence.

12. The adaptive Viterbi equalizing method of claim 10, wherein the step (c) comprises:
generating a delay signal by delaying the received signal for a predetermined time;
generating the error amount according to the delay signal, the plurality of channel responses, and the plurality of hard-decision values;
generating a correct probability of detection according to the soft-decision value; and
adjusting the plurality of channel responses according to the correct probability of detection and the error amount.

13. The adaptive Viterbi equalizing method of claim 12, wherein the predetermined time corresponds to a sum of the time for equalizing the specific original symbol and the time for generating the soft-decision value corresponding to the specific original symbol.

14. The adaptive Viterbi equalizing method of claim 12, wherein before the step (c) is performed, the adaptive Viterbi equalizing method further comprises:
equalizing the training sequence according to the initial value of the plurality of channel responses, generates a plurality of soft-decision values according to the training sequence, and generating a mean value and a variance according to the plurality of soft-decision values of the training sequence;
and after the step (c) is completed, the adaptive Viterbi equalizing method further comprises:
generating the correct probability of detection according to the mean value, variance, and the soft-decision value.

15. The adaptive Viterbi equalizing method of claim 12 utilizes a product of the correct probability of detection and the error amount to adjust the plurality of channel responses.

16. The adaptive Viterbi equalizing method of claim 15 further comprises:
controlling an adjusting range of the plurality of channel responses by regulating the product according to an adjusting coefficient.

17. The adaptive Viterbi equalizing method of claim 10, wherein the step (c) adjusts the plurality of channel responses according to the soft-decision value and the error amount between the specific original symbol and the reconstructed symbol to update the plurality of channel responses for equalizing the specific original symbol.

18. The adaptive Viterbi equalizing method of claim 10 applied in a Global System for Mobile Communications (GSM).
